(19) United States
(12) Patent Application Publication
(10) Pub. No.: US 2019/0096444 A1
(43) Pub. Date: Mar. 28, 2019

(54) CIRCUIT FOR MEMORY SYSTEM AND ASSOCIATED METHOD

(71) Applicant: Realtek Semiconductor Corp., HsinChu (TW)

(72) Inventors: Chih-Chia Chiu, New Taipei City (TW); Ruey-Beei Wu, Taipei (TW); Ting-Ying Wu, Hsinchu County (TW); Wen-Shan Wang, Hsinchu County (TW); GERCHIH CHOU, San Jose, CA (US)

(21) Appl. No.: 15/713,718

(22) Filed: Sep. 25, 2017

(51) Int. Cl. G11C 5/14; H05K 1/02; G11C 5/06; H05K 1/11

(52) U.S. Cl. CPC G11C 5/14; H05K 1/112; G11C 5/066; H05K 1/025

(57) ABSTRACT

A circuit for a memory system including a plurality of memories, including: a plurality of connection traces coupled in series, each connection trace having a first end, and a second end coupled to a terminal of a memory of the plurality of memories; wherein an equivalent impedance of a first connection trace of the plurality of connection traces is different with the equivalent impedance of the second connection trace of the plurality of connection traces, the first connection trace being coupled to the second connection trace in series.

### BACKGROUND OF THE INVENTION

### 1. Field of the Invention

The present invention relates to a circuit for a memory system and an associated method.

### 2. Description of the Prior Art

Memory systems such as Solid State Device (SSD) or Double Data Rate (DDR) systems, utilize a star topology or a fly-by topology for the memories therein. FIG. 1 illustrates a star topology and a fly-by topology in the prior art. As shown in sub-diagram (A) of FIG. 1, a memory system 110 has a plurality of memory blocks FLASH 1, FLASH 2, FLASH 3, and FLASH 4 arranged in the star topology, and is driven by the controller (e.g. memory controller) 111, wherein each memory block may include more than one memory. For example, the memory system 110 is an SSD system, and each memory included therein is an SSD. As shown in sub-diagram (B) of FIG. 1, a memory system 120 has a plurality of memories Ml-M8 arranged in the fly-by topology, and is driven by the controller (e.g. memory controller) 121. For example, the memory system 120 is a DDR system, and each memory therein is a DDR Synchronous Dynamic Random Access Memories (SDRAM) . The star topology shown in sub-diagram (A) of FIG. 1 is suitable for high speed applications such as the SSD system. The fly-by topology generally has a long wire structure, and the length of wire (or the impedance) between two adjacent memories may be the same, resulting in a more severe transmission line signal reflection for the memory closest to the controller.

### SUMMARY OF THE INVENTION

The present invention therefore provides a circuit for a memory system and an associated method to solve the abovementioned problem.

According to an embodiment of the present invention, a circuit for a memory system including a plurality of memories is disclosed. The circuit includes a plurality of connection traces coupled in series. Each connection trace has a first end, and a second end coupled to a terminal of a memory of the plurality of memories. An equivalent impedance of a first connection trace of the plurality of connection traces is different with the equivalent impedance of the second connection trace of the plurality of connection traces, and the first connection trace is coupled to the second connection trace in series.

According to an embodiment of the present invention, a method for a memory system including a plurality of memories is disclosed. The method includes a step of coupling a plurality of connection traces in series, in which each connection trace has a first end, and a second end coupled to a terminal of a memory of the plurality of memories. An equivalent impedance of a first connection trace of the plurality of connection traces is different with the equivalent impedance of the second connection trace of the plurality of connection traces, the first connection trace being coupled to the second connection trace in series.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a star topology and a fly-by topology employed by a conventional memory system.

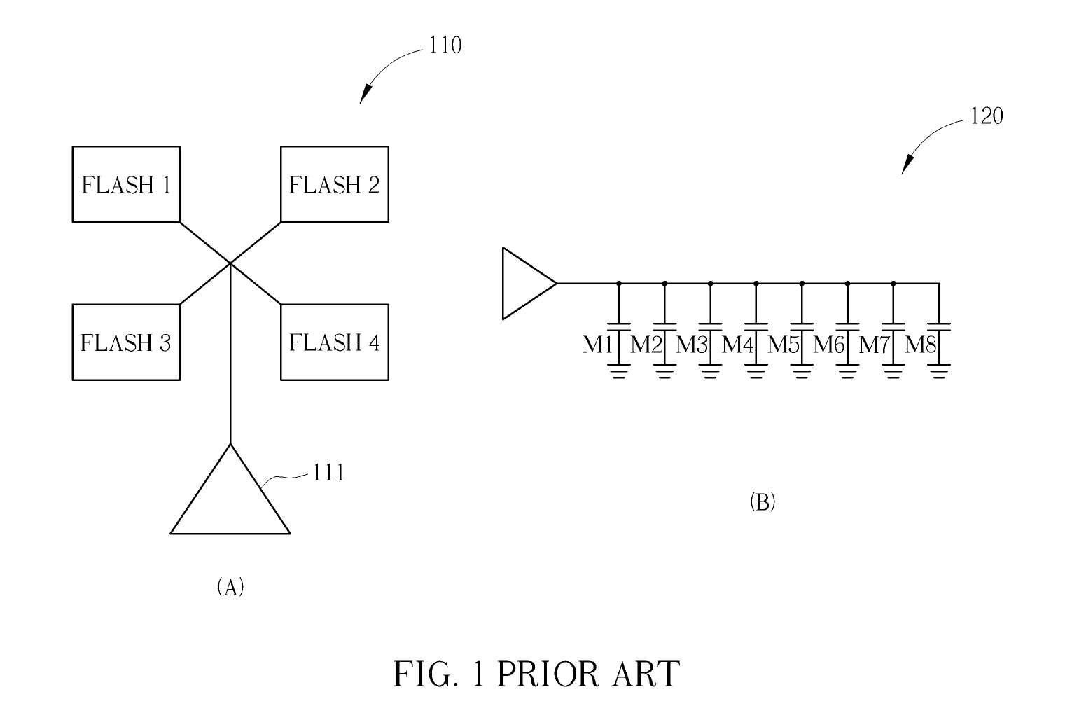

FIG. 2 is a diagram illustrating a driving circuit of a memory system according to an embodiment of the present invention.

FIG. 3 is a diagram illustrating a driving circuit of a memory system according to another embodiment of the present invention.

FIG. 4 is a diagram illustrating a driving unit of the driving circuit shown in FIG. 3.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should not be interpreted as a close-ended term such as “consist of”. Also, the term “couple” is intended to mean either an indirect or direct electrical connection. Accordingly, if one device is coupled to another device, that connection may be through a direct electrical connection, or through an indirect electrical connection via other devices and connections.

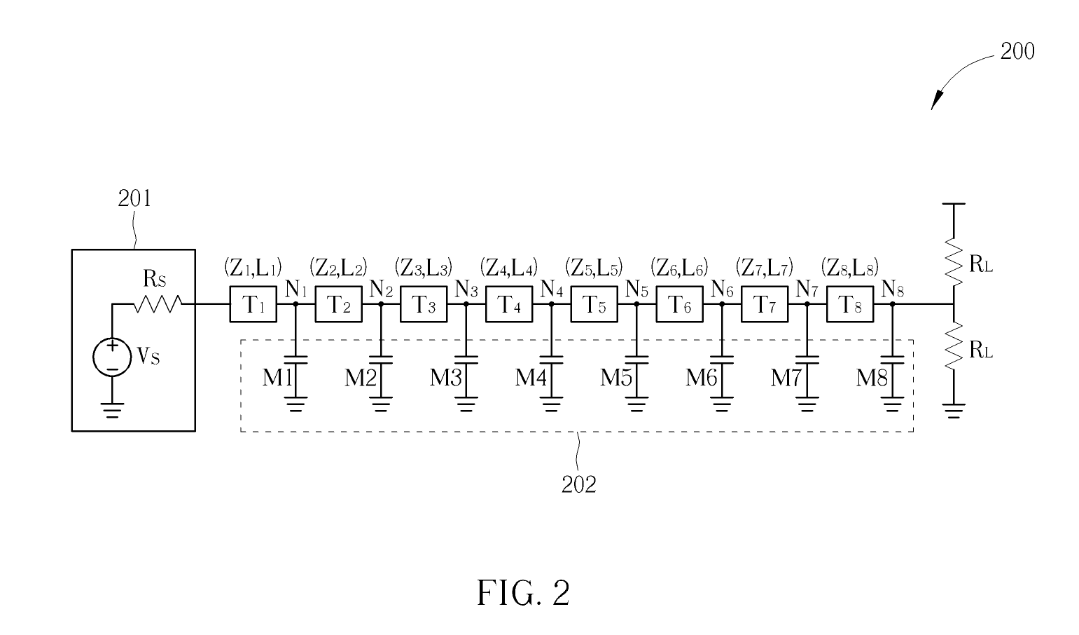

As mentioned above, for a memory system employing the fly-by topology, the impedances implemented by metal connection traces in a layout connecting the memories therein will be the same as the distance between those memories are equal. Poor performance is expected due to the severe reflection. FIG. 2 is a diagram illustrating a driving circuit 200 of a memory system according to an embodiment of the present invention. The memory system 202 includes a plurality of memories M1, M2, M3, M4, M5, M6, M7 and M8. Those skilled in the art will understand that the plurality of memories M1-M8 is equivalent to a plurality of capacitors as depicted in FIG. 2. It should be noted that the number of memories included in the memory system 202 is not a limitation of the present invention. For example, the memory system 202 can include more than one memory (e.g. 2, 4, 8 or even more memories) , depending upon the actual design considerations. The driving circuit 200 includes a plurality of connection traces T1, T2, T3, T4, T5, T6, T7, and T8, wherein the connection traces T1-T8 are implemented with metal by lengths L₁, L₂, L₃, L₄, L₅, L₆, L₇ and L₈ respectively, in which the equivalent impedances for the connection traces T₁-T₈ are Z₁, Z₂, Z₃, Z₄, Z₅, Z₆, Z₇ and Z₈, respectively, as shown in FIG. 2. Each of the plurality of memories M1-M8 in the memory system 202 has a terminal coupled to one end of one of the plurality of connection traces T₁-T₈, and every two memories in the plurality of memories M1-M8 are separated by one of the plurality of connection traces T₁-T₈.

The driving circuit 200 further includes a controller (e.g. memory controller) 201 that includes a driving source Vs and a resistor Rs, and that is coupled to the plurality of connection traces T₁-T₈. The connection trace T₁ and the memory M1 can be considered as a low pass filter, the connection trace T₂ and the memory M2 can be considered as another low pass filter, and so on and so forth. For memory M1 having capacitance of Z₁, the desired operation frequency or cutoff frequency of the low pass filter which consists of the connection trace T₁ and the memory M1 can be set by adjusting the length L₁ of the connection trace T₁ , in order to filter the driving voltage signal generated by the driving source Vs. Likewise, the desired operation frequency of the low pass filter which consists of the connection trace T₂ and the memory M2 can be obtained by adjusting the length L₂ of the connection trace T₂, the desired operation frequency of the low pass filter which consists of the connection trace T₃ and the memory M₃ can be obtained by adjusting the length L₃ of the connection trace T₃, and so on and so forth. The driving signal is then transmitted to the termination resistors (e.g. load resistance R_{L} shown in FIG. 2) . In some embodiments, termination resistors are implemented in the memory furthest from the controller 201 (e.g. memory M8).

The reflection for the driving signal can thereby be suppressed/mitigated when observed from terminals N₁, N₂, N₃, N₄, N₅, N₆, N₇, and N₈ shown in FIG. 2. The maximum eye diagram for the driving signal can be observed from the testing equipment. This greatly improves the performance.

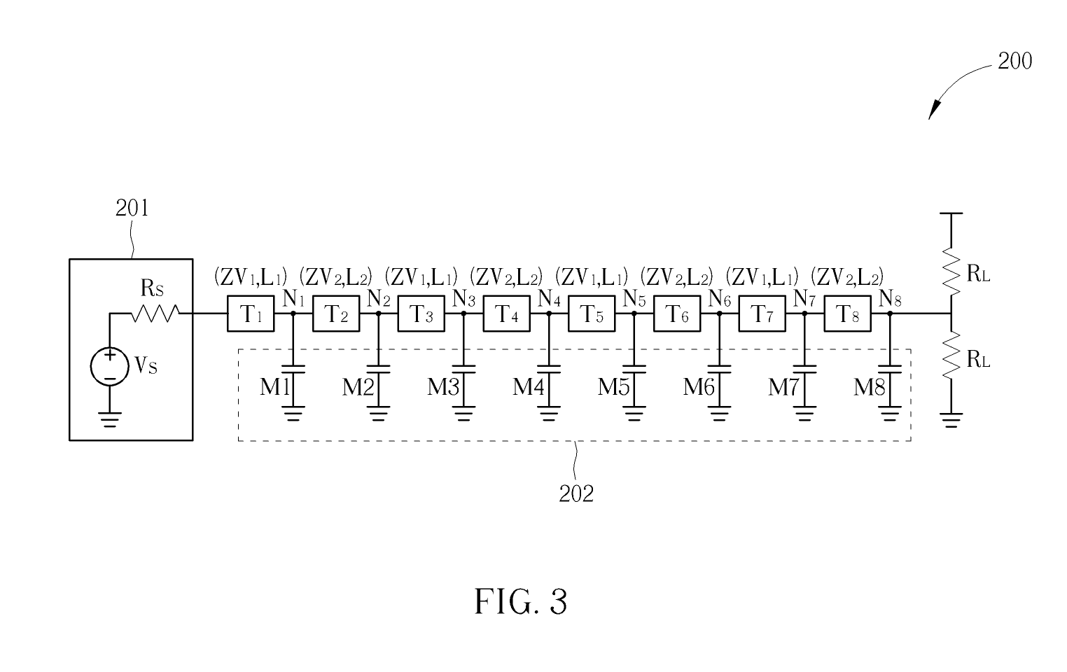

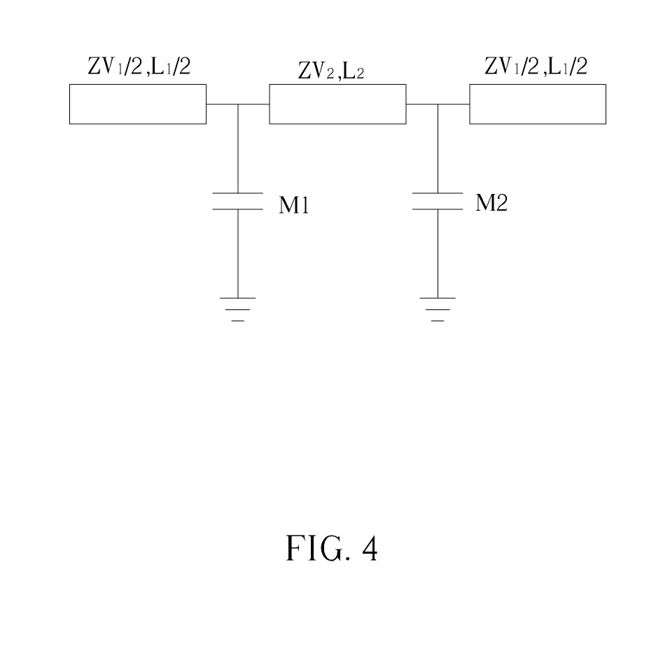

It should be noted that the impedances of the connection traces T₁-T₈ can be adjusted not only by the length, but also by the width, or by using a different types of metal or material. In addition, the equivalent impedance for the connection traces T₁-T₈ in this embodiment are marked by different labels (i.e. Z₁-Z₈) ; however, the equivalent impedance for some traces can also be the same. FIG. 3 is a diagram illustrating the driving circuit 200 of a memory system according to another embodiment of the present invention. In this embodiment, the impedances Z₁, Z₃, Z₅, Z₇ shown in FIG. 2 are set by the same value ZV₁, while the impedances Z₂, Z₄, Z₆, Z₈ shown in FIG. 2 are set by the same value ZV₂, where ZV₁≠ZV₂. Referring to FIG. 4 illustrating yet another embodiment of the driving circuit for a memory system including at least two memories (e.g. M1 and M2) . The driving circuit includes two different connection traces coupled in series and having impedances ZV₁/2 and ZV₂ that are different in values (a memory controller is not shown here) . The driving circuit and the memories M1, M2 can be regarded as a filter arranged for filtering a particular frequency band, wherein only the signals having frequency in the range of the frequency band are allowed to be passed or transmitted to the memories. The driving circuits as shown in FIG. 4 can be used as building blocks that are coupled in series to form a driving circuit such as the one shown in FIG. 3.

In another example, the impedances Z₁, Z₂, Z₃, Z₄, Z₅, Z₆, Z₇ are set by the same value ZV₁, while the impedance Z₈ is set by a value ZV₂, where ZV₁≠ZV₂. In yet another example, all the impedances Z₁-Z₈ are different from one another. In other words, the impedances Z₁-Z₈ can be any value as long as the reflection can be suppressed/mitigated and/or the eye diagram for the driving signal can be maximized.

Those skilled in the art will readily observe that numerous modifications and alterations of the device and method may be made while retaining the teachings of the invention. Accordingly, the above disclosure should be construed as limited only by the metes and bounds of the appended claims.

1. A circuit for a memory system including a plurality of memories, comprising:
a plurality of groups of connection traces coupled in series, each group of connection traces at least comprising a first connection trace and a second connection trace; each connection trace having a first end, and a second end coupled to a terminal of a memory of the plurality of memories;
wherein an equivalent impedance of the first connection trace is different from an equivalent impedance of the second connection trace, and the first connection trace is coupled to the second connection trace in series.

2. The circuit of claim 1, further comprising:
a controller, comprising:
a driving voltage source coupled to the plurality of groups of connection traces connected in series, wherein the driving voltage source is arranged to provide a driving voltage to the plurality of memories;
and
a source resistance, coupled between the driving voltage source and the plurality of groups of connection traces.

3. The circuit of claim 1, wherein the plurality of memories are a plurality of Double Data Rate Synchronous Dynamic Random Access Memories (DDR SDRAMs).

4. The circuit of claim 1, wherein the plurality of memories are a plurality of Solid State Disks (SSDs).

5. The circuit of claim 1, wherein each of the plurality of memories has another terminal coupled to a predetermined voltage.

6. The circuit of claim 5, wherein the predetermined voltage is ground.

7. The circuit of claim 1, wherein a length of the first connection trace is different from a length of the second connection trace.

8. A method for a memory system including a plurality of memories, comprising:
coupling a plurality of groups of connection traces in series, each group of connection traces at least comprising a first connection trace and a second connection trace; each connection trace having a first end, and a second end coupled to a terminal of a memory of the plurality of memories;
wherein an equivalent impedance of the first connection trace is different from an equivalent impedance of the second connection trace, and the first connection trace is coupled to the second connection trace in series.

9. The method of claim 8, further comprising:
utilizing a driving voltage source coupled to the plurality of groups of connection traces connected in series, wherein the driving voltage source is arranged to provide a driving voltage to the plurality of memories; and
coupling a source resistance between the driving voltage source and the plurality of groups of connection traces.

10. The method of claim 8, wherein the plurality of memories are a plurality of Double Data Rate Synchronous Dynamic Random Access Memories (DDR SDRAMs).

11. The method of claim 8, wherein the plurality of memories are a plurality of Solid State Disks (SSDs).

12. The method of claim 8, wherein each of the plurality of memories has another terminal coupled to a predetermined voltage.

13. The method of claim 12, wherein the predetermined voltage is ground.

14. The method of claim 8, wherein a length of the first connection trace is different from a length of the second connection trace.

15. The circuit of claim 1, wherein each group of connection traces further comprises a third connection trace coupled between the second connection trace and the first connection trace, wherein an equivalent impedance of the third connection trace is different from the equivalent impedances of the first connection trace and the second connection trace.

16. The circuit of claim 15, wherein each group of connection traces further comprises a fourth connection trace coupled between the third connection trace and the first connection trace, wherein an equivalent impedance of the fourth connection trace is different from the equivalent impedances of the first connection trace, the second connection trace and the third connection trace.

17. The circuit of claim 1, wherein the second end of a last connection trace of the plurality of groups of connection traces is coupled between a first terminating resistor and a second terminating resistor, wherein the first terminating resistor and the second terminating resistor are further coupled between a voltage source and ground.

18. The method of claim 8, wherein each group of connection traces further comprises a third connection trace coupled between the second connection trace and the first connection trace, wherein an equivalent impedance of the third connection trace is different from the equivalent impedances of the first connection trace and the second connection trace.

19. The method of claim 18, wherein each group of connection traces further comprises a fourth connection trace coupled between the third connection trace and the first connection trace, wherein an equivalent impedance of the fourth connection trace is different from the equivalent impedances of the first connection trace, the second connection trace and the third connection trace.

20. The method of claim 8, wherein the second end of a last connection trace of the plurality of groups of connection traces is coupled between a first terminating resistor and a second terminating resistor, wherein the first terminating resistor and the second terminating resistor are further coupled between a voltage source and ground.
